(19) United States
(12) Patent Application Publication
(10) Pub. No.: US 2023/0385493 A1
(43) Pub. Date: Nov. 30, 2023

(54) REDACTING NETWORK-ON-CHIP FUNCTIONALITY IN A SYSTEM-ON-CHIP ARCHITECTURE

(71) Applicant: University of Florida Research Foundation, Incorporated, Gainesville, FL (US)

(72) Inventors: Sandip RAY, Gainesville, FL (US); Maneesh MERUGU, Gainesville, FL (US); Dipal HALDER, Gainesville, FL (US)

(21) Appl. No.: 18/325,649

(22) Filed: May 30, 2023

Related U.S. Application Data
(60) Provisional application No. 63/347,244, filed on May 31, 2022.

(51) Int. Cl. G06F 30/327; G06F 30/3323; H03K 19/17728

(52) U.S. Cl. CPC G06F 30/327; G06F 30/3323; H03K 19/17728

(57) ABSTRACT

Various embodiments of the present disclosure provide for redacting Network-on-Chip (NoC) functionality in a System-on-Chip (SoC). In one example, an embodiment provides for receiving a Register Transfer Level (RTL) source code that models a design for an SoC via a hardware description language, converting one or more routing tables related to the RTL source code with one or more configurable logic tables, replacing one or more connections related to the RTL source code with one or more programmable multiplexers, generating a transformed RTL source code for the SoC based on the one or more configurable logic tables and the one or more programmable multiplexers, and/or providing an attack-resistant obfuscated SoC based on the transformed RTL source code.

### CROSS REFERENCE TO RELATED APPLICATIONS

This application claims priority to U.S. Appl. No. 63/347,244 filed May 31, 2022, the contents of which are incorporated herein in its entirety by reference.

### GOVERNMENT SUPPORT

This invention was made with government support under HR0011-21-3-0001 awarded by US DEPARTMENT OF DEFENSE DARPA. The government has certain rights in the invention.

### TECHNICAL FIELD

The present application relates to the technical field of integrated circuits. In particular, the invention relates to security associated with integrated circuits.

### BACKGROUND

System-on-Chip (SoC) architectures may integrate third-party semiconductor cores such as, for example, hardware Intellectual Property (IP) cores that coordinate and/or communicate through a Network-on-Chip (NoC) fabric to provide various types of system functionality. NoCs generally provide on-chip communication using a set of routers connected in a topology customized for the target SoC. NoCs also generally enable integration of diverse heterogeneous IP cores with various interfacing protocols. However, communication of IP cores through the NoC fabric often introduce security vulnerabilities for the SoC. For example, since NoCs generally connect SoC components in a single substrate, unauthorized access and/or other attacks with respect to on-chip networks can undermine coordination and/or communication among IP cores integrated within an SoC. Furthermore, assets in an SoC generally communicate across different IP cores. For instance, an SoC can communicate across different IP cores during system boot. A security engine of an SoC can also communicate various digital rights management (DRM) keys and/or cryptographic keys to respective IP cores. Accordingly, NoCs are often vulnerable to snooping, reverse-engineering, Trojan attacks, and/or other security vulnerabilities. Moreover, while the same individual IP cores are generally used across different SoC products, NoC topologies and/or related communication patterns among IP cores are generally unique to a specific SoC target. As such, it is often difficult to identify security vulnerabilities in a specific communication sequence during validation of an SoC.

### SUMMARY

In general, embodiments of the present invention provide methods, apparatus, systems, computing devices, computing entities, and/or the like for redacting Network-on-Chip (NoC) functionality in a System-on-Chip (SoC). The details of some embodiments of the subject matter described in this specification are set forth in the accompanying drawings and the description below. Other features, aspects, and advantages of the subject matter will become apparent from the description, the drawings, and the claims.

In an embodiment, a method for redacting NoC functionality in a SoC architecture is provided. The method provides for receiving a Register Transfer Level (RTL) source code that models a design for an SoC via a hardware description language, converting one or more routing tables related to the RTL source code with one or more configurable logic tables, replacing one or more connections related to the RTL source code with one or more programmable multiplexers, generating a transformed RTL source code for the SoC based on the one or more configurable logic tables and the one or more programmable multiplexers, and/or providing an attack-resistant obfuscated SoC based on the transformed RTL source code.

In another embodiment, an apparatus for redacting NoC functionality in a SoC architecture is provided. The apparatus comprises at least one processor and at least one memory including program code. The at least one memory and the program code is configured to, with the at least one processor, cause the apparatus to receive an RTL source code that models a design for an SoC via a hardware description language, convert one or more routing tables related to the RTL source code with one or more configurable logic tables, replace one or more connections related to the RTL source code with one or more programmable multiplexers, generate a transformed RTL source code for the SoC based on the one or more configurable logic tables and the one or more programmable multiplexers, and/or provide an attack-resistant obfuscated SoC based on the transformed RTL source code.

In yet another embodiment, a non-transitory computer storage medium comprising instructions for redacting NoC functionality in a SoC architecture is provided. The instructions are configured to cause one or more processors to at least perform operations configured to receive an RTL source code that models a design for an SoC via a hardware description language, convert one or more routing tables related to the RTL source code with one or more configurable logic tables, replace one or more connections related to the RTL source code with one or more programmable multiplexers, generate a transformed RTL source code for the SoC based on the one or more configurable logic tables and the one or more programmable multiplexers, and/or provide an attack-resistant obfuscated SoC based on the transformed RTL source code.

### BRIEF DESCRIPTION OF THE DRAWINGS

Reference will now be made to the accompanying drawings, which are not necessarily drawn to scale, and wherein:

FIG. 1 illustrates an exemplary system associated with an obfuscation architecture related to redacting Network-on-Chip (NoC) functionality in a System-on-Chip (SoC), according to one or more embodiments of the present disclosure;

FIG. 2 illustrates an exemplary system associated with topology obfuscation, according to one or more embodiments of the present disclosure;

FIG. 3 illustrates an exemplary NoC security development cycle, according to one or more embodiments of the present disclosure;

FIG. 4 illustrates an exemplary lifecycle of a hardware intellectual property (IP) core, according to one or more embodiments of the present disclosure;

FIG. 5 illustrates a system associated with topology obfuscation according to one or more embodiments of the present disclosure;

FIG. 6 illustrates an SoC system associated with an NoC-based SoC design according to one or more embodiments of the present disclosure;

FIG. 7 illustrates transformation of an SoC system according to one or more embodiments of the present disclosure;

FIG. 8 illustrates another transformation of an SoC system according to one or more embodiments of the present disclosure;

FIG. 9 illustrates an activation package loader circuit according to one or more embodiments of the present disclosure;

FIG. 10 illustrates a transformed SoC according to one or more embodiments of the present disclosure;

FIG. 11A illustrates an SoC according to one or more embodiments of the present disclosure;

FIG. 11B illustrates another SoC according to one or more embodiments of the present disclosure;

FIG. 11C illustrates another SoC according to one or more embodiments of the present disclosure;

FIG. 12 illustrates another system associated with topology obfuscation according to one or more embodiments of the present disclosure; and

FIG. 13 illustrates another system associated with topology obfuscation according to one or more embodiments of the present disclosure;

FIG. 14 illustrates a flowchart of a method for redacting NoC functionality in a SoC architecture according to one or more embodiments of the present disclosure; and

FIG. 15 illustrates a schematic of a computing entity that may be used in conjunction with one or more embodiments of the present disclosure.

### DETAILED DESCRIPTION

The present disclosure more fully describes various embodiments with reference to the accompanying drawings. It should be understood that some, but not all, embodiments are shown and described herein. Indeed, the embodiments may take many different forms, and accordingly, this disclosure should not be construed as limited to the embodiments set forth herein. Rather, these embodiments are provided so that this disclosure will satisfy applicable legal requirements. Like numbers refer to like elements throughout.

System-on-Chip (SoC) architectures may integrate third-party semiconductor cores such as, for example, hardware Intellectual Property (IP) cores that coordinate and/or communicate through a Network-on-Chip (NoC) fabric to provide various types of system functionality. The NoC fabrics can be configured to coordinate among integrated hardware blocks of the SoC. As mentioned above, communication of IP cores through the NoC fabric often introduces security vulnerabilities for the SoC. Accordingly, NoCs in SoC architectures are often vulnerable to snooping, reverse-engineering, Trojan attacks, and/or other security vulnerabilities. In an example, a third-party semiconductor foundry may attempt to reverse-engineer the NoC topology and/or routing logic of an SoC.

Hardware obfuscation is a technique to protect hardware IP cores against piracy attacks and/or other security vulnerabilities. Traditional obfuscation techniques generally rely on preventing an attacker from black-box usage of a hardware IP core and/or understanding a design-intent of a hardware IP core, thereby preventing an unauthorized third-party from gaining access to the hardware IP core or replicating a design of the hardware IP core. However, traditional obfuscation techniques are generally implemented at the IP Level. For example, certain obfuscation techniques (e.g., a functional obfuscation technique, etc.) are applied to an early stage of a life cycle of a hardware IP core. Alternatively, other traditional obfuscation techniques (e.g., a physical obfuscation technique, etc.) are applied in a fabrication stage of a hardware IP core. Other traditional obfuscation techniques such as, for example, state space obfuscation techniques, add locking logic circuits at strategic locations of a combinational block to obfuscate a finite state machine of a design. However, traditional obfuscation techniques are still vulnerable to piracy attacks and/or other security vulnerabilities due to, for example, the deterministic techniques being identified and/or bypassed by an attacker.

Authenticated encryption is another technique to protect hardware IP cores against piracy attacks and/or other security vulnerabilities. For example, authenticated encryption techniques for NoC security provide encryption-decryption of data packets emanating out of an IP core in the SoC. Other techniques such as bit shuffling, heuristic-based fault detection models, and/or route randomization can alternatively be employed to protect hardware IP cores against piracy attacks and/or other security vulnerabilities. However, these traditional techniques to protect hardware IP cores against piracy attacks and/or other security vulnerabilities primarily focus on security vulnerabilities related to data integrity, denial of service, and/or side/covert channel attacks.

To address these and/or other issues, various embodiments described herein relate to a novel framework for redacting NoC functionality in an SoC architecture. In various embodiments, an obfuscated NoC (OBNOC) infrastructure can be provided to protect NoC fabrics against piracy attacks and/or other security vulnerabilities. The OBNOC can provide an obfuscation methodology for system-level interactions of SoC designs. For example, obfuscation can be achieved by removing one or more portions of hardware functionality for an NoC and/or an SoC. In contrast, traditional obfuscation techniques achieve design obfuscation by adding additional design states as a means to confuse a malicious third-party actor. In various embodiments, obfuscation related to system-level obfuscation-based safety measures for an SoC can be provided. For example, NoC attacks and/or other security vulnerabilities related to SoCs can be mitigated by employing one or more obfuscation techniques as disclosed herein. The one or more obfuscation techniques can be related to routers and/or NoC fabric topologies. The one or more obfuscation techniques can also provide system-level obfuscation to ensure safety and/or security of on-chip components. For example, provable assurance of protection of obfuscated topologies against reverse-engineering attacks can be provided.

In various embodiments, one or more router connections of an NoC fabric can be systematically replaced with respective switches that can be programmed after fabrication. The respective switches can include a specific set of state elements, only one of which may correspond to an original topology of the NoC fabric. The switch configuration (e.g., specific set of state elements) can correspond to the original topology as an activation package. In various embodiments, an obfuscation technique that replaces static NoC routing tables with configurable logic tables can be employed. Additionally or alternatively, an obfuscation technique that replaces static fabric connections with a combination of programmable multiplexers (MUXs) related to switch configurations can be employed. For example, an interconnect topology can be transformed through a switching architecture that systematically redacts connection structures using programmable MUXs. The programmable MUXs can be controlled by programmable registers. Accordingly, inter-IP communications can be derived based on the configurable tables and/or configurable switches rather than being derived from SoC design alone. By employing one or more obfuscation techniques as disclosed herein, provable redaction of NoC functionality can be provided via switch configurations that induce a number of topologies where only one of which corresponds to an original topology of an NoC fabric. Moreover, by employing one or more obfuscation techniques as disclosed herein, improved resource utilization and/or improved system latency for an SoC can be provided while minimizing power supply utilization.

In various embodiments, enhanced security of an NoC fabric can be provided by obfuscating an underlying NoC interconnect architecture. The enhanced security of an NoC fabric can also provide a more advanced and/or secure SoC. By obfuscating an underlying NoC interconnect architecture, protection of IP cores and/or other security critical assets of an SoC against targeted attacks and/or other security vulnerabilities can also be provided. In various embodiments, Register Transfer Level (RTL) source code for an SoC and/or information related to an underlying NoC topology can be provided as input to an obfuscation framework to provide a transformed version of a design of the SoC. In various embodiments, the obfuscation framework can replace underlying routing logic with highly customizable configurable logic blocks. The configurable logic blocks can be, for example, one or more configurable tables such as one or more lookup tables.

In various embodiments, the obfuscation framework can additionally or alternatively provide programmable interconnects coupled with additional logic for topology obfuscation and/or to provide individual configurable parameters. The individual configurable parameters can be singular configurable parameters configured as an activation package to configure the programmable logic. The transformed design for the SoC can be functionally equivalent to the original SoC design when the correct configuration and/or activation package is provided. Accordingly, a transformed SoC design that replaces original logic and the obfuscated topology can be provided to a foundry for manufacturing for increased security against a malicious third-party actor. For example, an attack-resistant obfuscated SoC with improved security with respect to the correct interconnect architecture and/or underlying topology can be provided. Moreover, absence of routing logic with respect to the transformed SoC design would make it computationally impossible for a malicious third-party actor to determine correct connections for the SoC. In various embodiments, the transformed design for the SoC can be related to system-level interactions and/or can re-purpose available microarchitectural components available in the SoC. Additionally, the transformed design for the SoC can be provided without new custom structures specifically for the obfuscation. As such, the transformed design for the SoC can be configured to mitigate reverse-engineering of one or more portions of the SoC through a malicious third-party actor such as, for example, a brute-force adversary attack.

As disclosed herein, the term ‘obfuscation’ may be used interchangeably to represent electronic hardware obfuscation or logic locking techniques.

Additionally, as disclosed herein, RTL source code can model an integrated circuit (e.g., an SoC, a semiconductor core, etc.) based on flow of signals between hardware components and/or logical operations associated with the signals. For example, a hardware description language can be employed to implement RTL source code, which provides a high-level description of an integrated circuit.

### A. Exemplary Network-On-Chip Interconnect Security Via Obfuscation

In various embodiments, NoC routing can be provided via an RTL-RTL transformation. For example, an obfuscation architecture can receive an RTL for an SoC and/or data related to a router table format. The RTL provided to the obfuscation architecture can be related to a particular NoC topology (e.g., a static NoC topology) for the SoC. Based on the RTL and/or the data related to the router table format, a transformed RTL can be provided via one or more obfuscation processes.

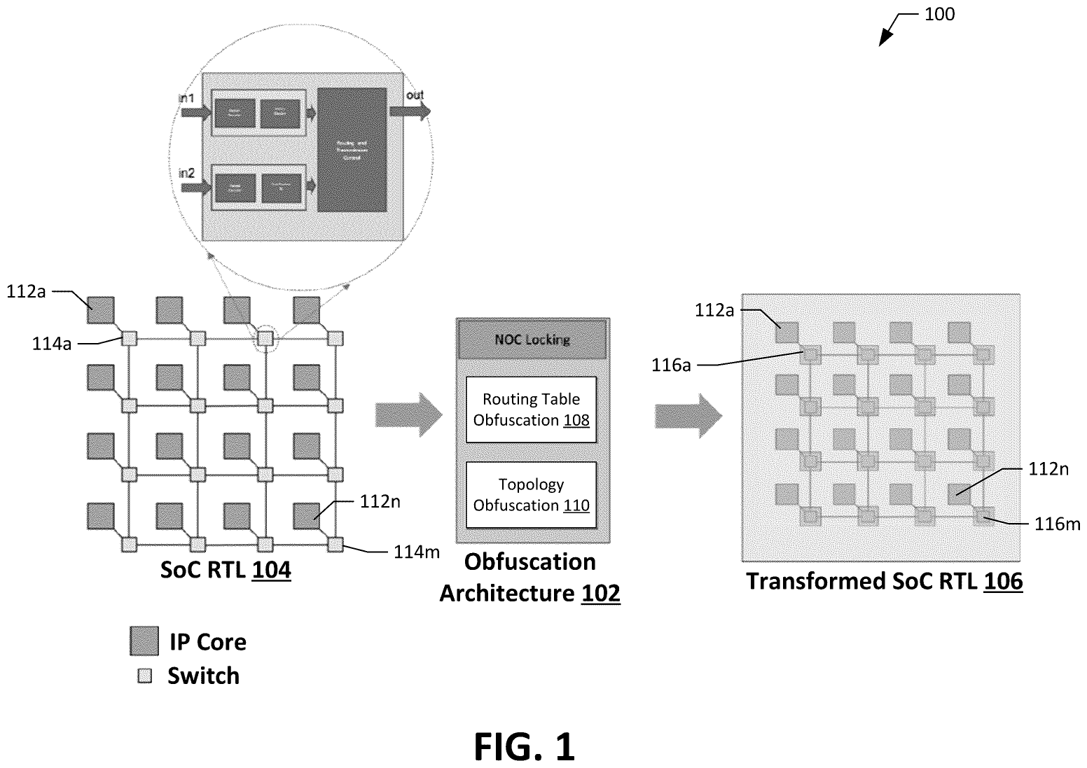

FIG. 1 illustrates a system 100 associated with an obfuscation architecture related to redacting NoC functionality in an SoC according to one or more embodiments of the present disclosure. The system 100 includes an obfuscation architecture 102 that transforms an SoC RTL 104 into a transformed SoC RTL 106. The obfuscation architecture 102 can transform the SoC RTL 104 into the transformed SoC RTL 106 via one or more obfuscation processes. The SoC RTL 104 can be an RTL source code that models an SoC based on flow of signals between hardware components and/or logical operations associated with the signals. For example, the SoC RTL 104 can be configured as a hardware description language that provides a high-level description of the SoC. The SoC can be an integrated circuit that includes one or more IP cores 112a-n and/or one or more switches 114a-m. Accordingly, in various embodiments, the SoC RTL 104 can be configured to describe the one or more IP cores 112a-n and/or the one or more switches 114a-m. However, it is to be appreciated that, in certain embodiments, the SoC RTL 104 can be an RTL source code that models a different type of hardware such as, for example, a semiconductor core or another type of integrated circuit. The one or more switches 114a-m can be respectively configured for routing and/or transmission control for data associated with the one or more IP cores 112a-n. In various embodiments, the one or more switches 114a-m can be respectively configured to receive data provided by an IP core from the one or more IP cores 112a-n and/or at least one switch from the one or more switches 114a-m. The one or more switches 114a-m can also be respectively configured to provide data to one or more other switches from the one or more switches 114a-m.

In one or more embodiments, the obfuscation architecture 102 can transform the SoC RTL 104 into the transformed SoC RTL 106 via routing table obfuscation 108 and/or topology obfuscation 110. The routing table obfuscation 108 can be configured for routing table obfuscation. In one or more embodiments, the routing table obfuscation 108 can be configured to replace one or more static NoC routing tables related to the SoC RTL 104 with one or more configurable logic tables. In various embodiments, the routing table obfuscation 108 can be configured to replace routing logic for the SoC RTL 104 with respective configurable tables. For example, the routing table obfuscation 108 can replace routing table metadata for the SoC RTL 104 with configurable table entries that can be configured (e.g., burnt) into configurable tables by a designer post manufacturing of the SoC. Configurable parameters for the routing (e.g., configuration parameters for the configurable tables) can be configured such that routing occurs through (e.g., routing occurs only through) configuration provided by the configurable parameters. Accordingly, a foundry and/or other manufacturer for the SoC can be provided with an empty structure for the routing logic to prevent a malicious third-party actor oblivious to the underlying routing logic for the SoC.

The topology obfuscation 110 can be configured for topology obfuscation. In one or more embodiments, the topology obfuscation 110 can be configured to replace static fabric connections related to the SoC RTL 104 with a combination of programmable multiplexers. In various embodiments, the topology obfuscation 110 can provide system-level design transformation with respect to the SoC RTL 104.

The transformed SoC RTL 106 can be a transformed RTL source code that models the SoC. For example, the SoC RTL 104 can be configured as a transformed hardware description language that provides a transformed description of the SoC. In various embodiments, the transformed SoC RTL 106 can be configured to describe the one or more IP cores 112a-n and/or one or more transformed switches 116a-m. The one or more transformed switches 116a-m can be obfuscated versions of the one or more switches 114a-m.

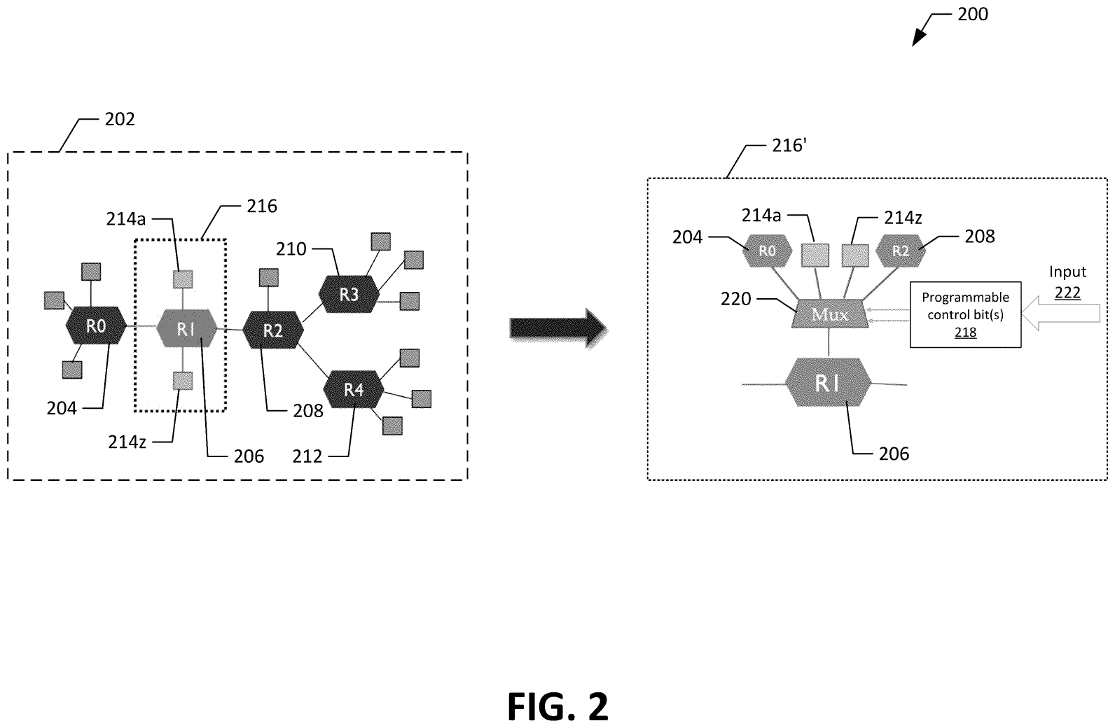

FIG. 2 illustrates a system 200 associated with topology obfuscation according to one or more embodiments of the present disclosure. For example, the system 200 can be related to one or more operations performed by the topology obfuscation 110. In various embodiments, the system 200 provides NoC interconnect transformation topology obfuscation. The system 200 includes an SoC architecture 202. The SoC architecture 202 can be, for example, an NoC-based SoC architecture configured as a tree topology. In certain embodiments, the SoC architecture 202 can be alternatively configured as a cycle network, a mesh network, or a torus network. The SoC architecture 202 can include a router 204 (e.g., R0), a router 206 (e.g., R1), a router 208 (e.g., R2), a router 210 (e.g., R3), and/or a router 212 (e.g., R4). The SoC architecture 202 can additionally include one or more other hardware components 214a-z. For example, the one or more other hardware components 214a-z can include one or more switches, one or more IP cores, and/or one or more other types of hardware components.

In an embodiment, the topology obfuscation 110 can replace an output link 216 of the router 206 with a transformed SoC architecture portion 216′ shown. For example, the transformed SoC architecture portion 216′ can be a transformation of the output link 216 of the router 206. The output link 216 can be, for example, an outgoing edge of the router R1. In various embodiments, the transformed SoC architecture portion 216′ can include a multiplexer 220 (e.g., MUX). The multiplexer 220 can be a programmable multiplexer that is controlled based on one or more programmable control bits 118 associated with input 222. In certain embodiments, the input 222 can be associated with the configurable parameters. In various embodiments, the switch 206 can be provided through the multiplexer 220 configured as a multiplexer or a demultiplexer to enable connection of the physical output link with the router 204, the router 208, the hardware component 214a, the hardware component 214z, and/or one or more other components in an original topology associated with the SoC architecture 202. In various embodiments, a specific component (e.g., the router 204, the router 208, the hardware component 214a, the hardware component 214z, and/or one or more other components in an original topology associated with the SoC architecture 202) to be connected to the switch 206 can be determined by the control of the multiplexer 220 via the one or more programmable bits 218. In various embodiments, the one or more programmable bits 218 can be configured as an activation package (e.g., an activation dataset) for the transformed SoC architecture portion 216′. Consequently, the topology associated with the transformed SoC architecture portion 216′ can be completely undefined in the absence of the one or more programmable bits 218 (e.g., the activation package). Accordingly, obfuscation can be provided to define a transformation such that one or more hardware components of an original SoC design are eliminated and/or replaced by dynamic tables and/or configurable switches.

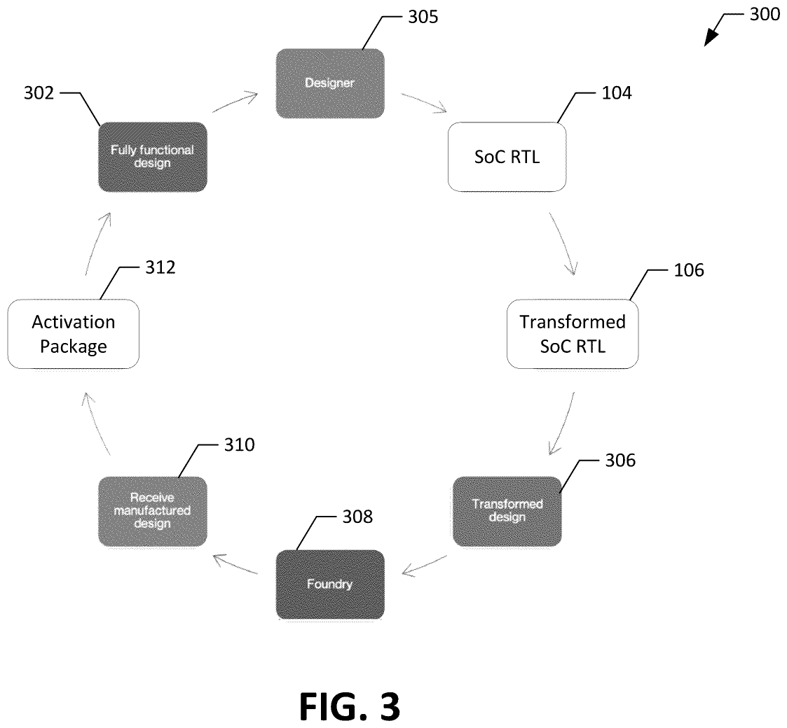

FIG. 3 illustrates an exemplary NoC security development cycle 300 according to one or more embodiments. In various embodiments, a fully functional design 302 of an SoC is converted (e.g., by a designer 305 by employing a computing device) into the SoC RTL 104. Additionally, the obfuscation architecture 102 can transform the SoC RTL 104 into the transformed SoC RTL 106. The transformed SoC RTL 106 can be employed to provide a transformed design 304 for the SoC. The transformed design 304 for the SoC can be employed by a foundry 308 to provide a manufactured design 310 for the SoC. The foundry 308 can be, for example, a semiconductor manufacturing system configured to manufacture the SoC. In order to provide the fully functional design 302 for the SoC based on the manufactured design 310 for the SoC, an activation package 312 can be employed. The activation package 312 can be, for example, the one or more programmable control bits 218 (e.g., configurable parameters) required to configure the replaced and/or programmable logic for the fully functional design 302 for the SoC.

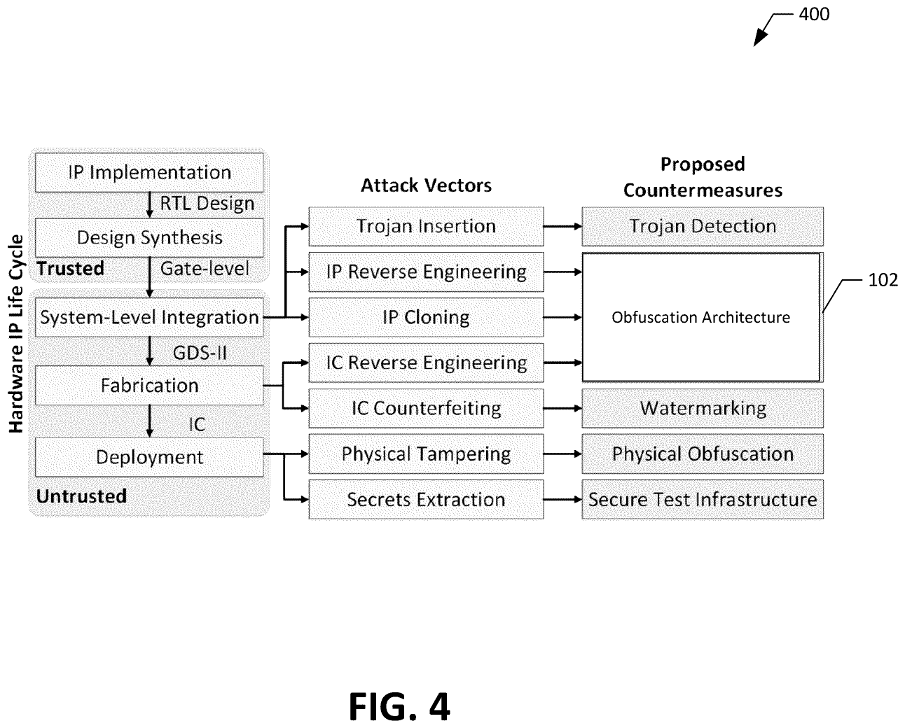

FIG. 4 illustrates an exemplary lifecycle 400 of a hardware IP core according to one or more embodiments. Untrusted parties may perform malicious activities to a hardware IP core at different phases of the lifecycle 400. According to various embodiments, the obfuscation architecture 102 can be employed to provide one or more countermeasures against IP reverse-engineering, IP cloning, Trojan insertion (e.g., Trojan attacks), and/or other security vulnerabilities during system-level integration and/or fabrication of an SoC. For instance, the obfuscation architecture 102 can mitigate IP piracy attacks and/or other malicious activity applied at an early development stage of the lifecycle 300. For example, untrusted parties may perform malicious activities to a hardware IP core at different phases. As such, a strong structural alteration of the SoC can be obtained for improved security against security vulnerabilities. Furthermore, a framework that is scalable to various SoC sizes and/or complexities can be provided.

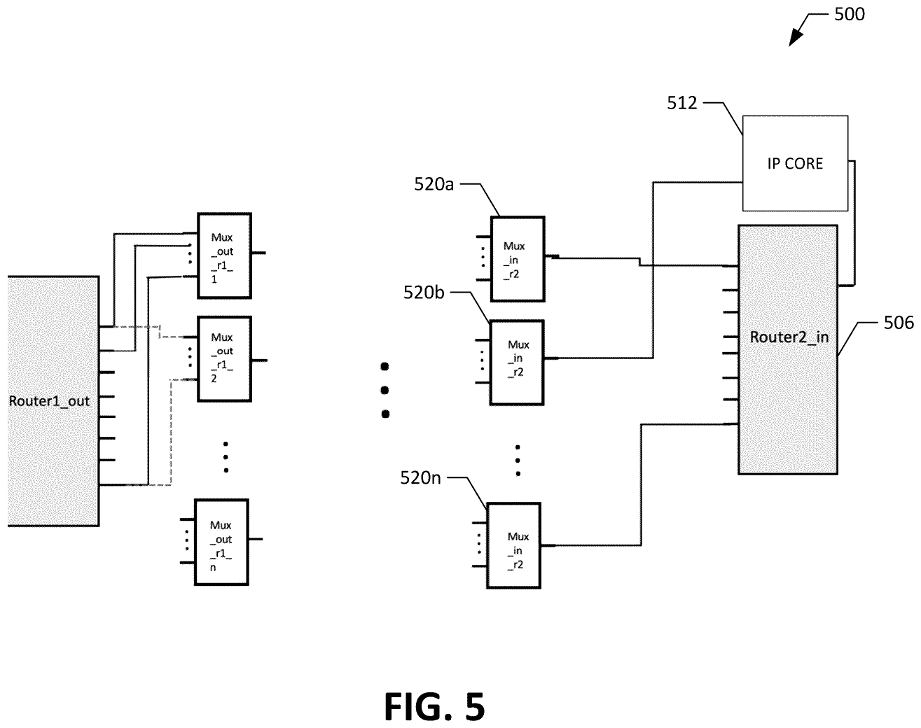

FIG. 5 illustrates a system 500 associated with topology obfuscation according to one or more embodiments of the present disclosure. The system 500 can provide a configurable multiplexer-demultiplexer implementation for one or more embodiments of the topology obfuscation 110. In various embodiments, the system 500 can provide an optimized implantation of the topology obfuscation 110. The system 500 includes an IP core 512, a router 506, and one or more multiplexers 520a-n. In various embodiments, the IP core 512 can be an IP core from the one or more IP cores 112a-n. The IP core 512 and the router 506 can correspond to at least a portion of an SoC architecture such as, for example, the SoC architecture 202. In various embodiments, the topology obfuscation 110 can replace one or more static fabric connections for the SoC architecture with the one or more multiplexers 520a-n. The one or more multiplexers 520a-n can be configured as a set of programmable multiplexers to provide optimized topology obfuscation. In various embodiments, the one or more multiplexers 520a-n can be configured for control based on one or more programmable bits (e.g., the one or more programmable control bits 118) in order to provide optimized topology obfuscation. In various embodiments, the one or more multiplexers 520a-n can be configured as a set of multiplexers to reduce multiplexer-demuliplexer heterogeneity associated with topology obfuscation.

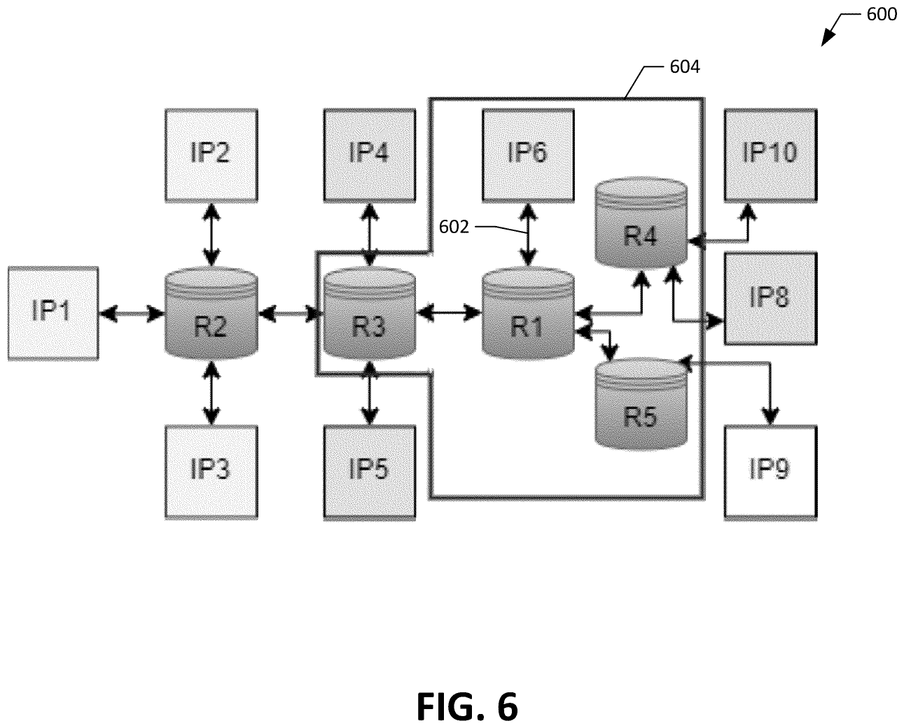

FIG. 6 illustrates an SoC system 600 associated with an NoC-based SoC design according to one or more embodiments of the present disclosure. The SoC system 600 can provide an NoC transformation topology obfuscation. Additionally, the NoC-based SoC design of the SoC system 600 can be implemented as a tree topology. The SoC system 600 includes five routers: R1, R2, R3, R4 and R5. The SoC system 600 also includes ten IP cores: IP1, IP2, IP3, IP4, IP5, IP6, IP7, IP8, IP9 and IP10. In an embodiment, a portion 602 of the SoC system 600 can be redacted. The portion 602 can correspond to a connection from the router R1 to the IP core IP6. To provide the redaction associated with the connection from the router R1 to the IP core IP6, a portion 604 of the SoC system 600 can be transformed.

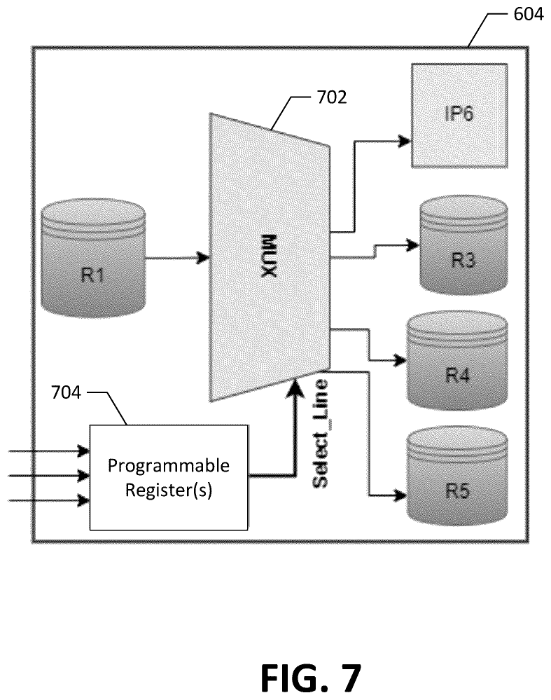

FIG. 7 illustrates the portion 604 associated with the transformation of the SoC system 600 according to one or more embodiments of the present disclosure. As illustrated in FIG. 7, the portion 604 of the SoC system 600 can be transformed to include a multiplexer 702 that is configured to conceal (e.g., transform) the connection from the router R1 to the IP core IP6. The multiplexer 702 can be controlled via a set of programmable registers 704. Additionally, the multiplexer 702 can be configured as a 1×4 multiplexer. In an embodiment, the router R1 is connected to an input of the multiplexer 702. Additionally, the IP core IP6, the router R3, the router R4 and the router R5 are connected to an output of the multiplexer 702. In various embodiments, the multiplexer 702 is configured as a demultiplexer switch. The set of programmable registers 704 can be programmed after fabrication of the SoC. Additionally, control bits (e.g., Select_Line) of the set of programmable registers 704 can determine which IP core is connected to the router R1. For example, if the set of programmable registers 704 is programmed with a defined bit value (e.g., bits 00), then the router R1 can be connected to the IP core IP6 via the multiplexer 702. However, if the set of programmable registers 704 is programmed with a different bit value (e.g., bits 01, bits 10 or bits 11), then the router R1 can be connected to the router R3, the router R4 or the router R5 via the multiplexer 702. For example, if the set of programmable registers 704 is programmed with a different defined bit value (e.g., bits 01), then the router R1 can be connected to the router R3 via the multiplexer 702. In another example, if the set of programmable registers 704 is programmed with another different defined bit value (e.g., bits 10), then the router R1 can be connected to the router R4 via the multiplexer 702. In yet another example, if the set of programmable registers 704 is programmed with another different defined bit value (e.g., bits 11), then the router R1 can be connected to the router R5 via the multiplexer 702.

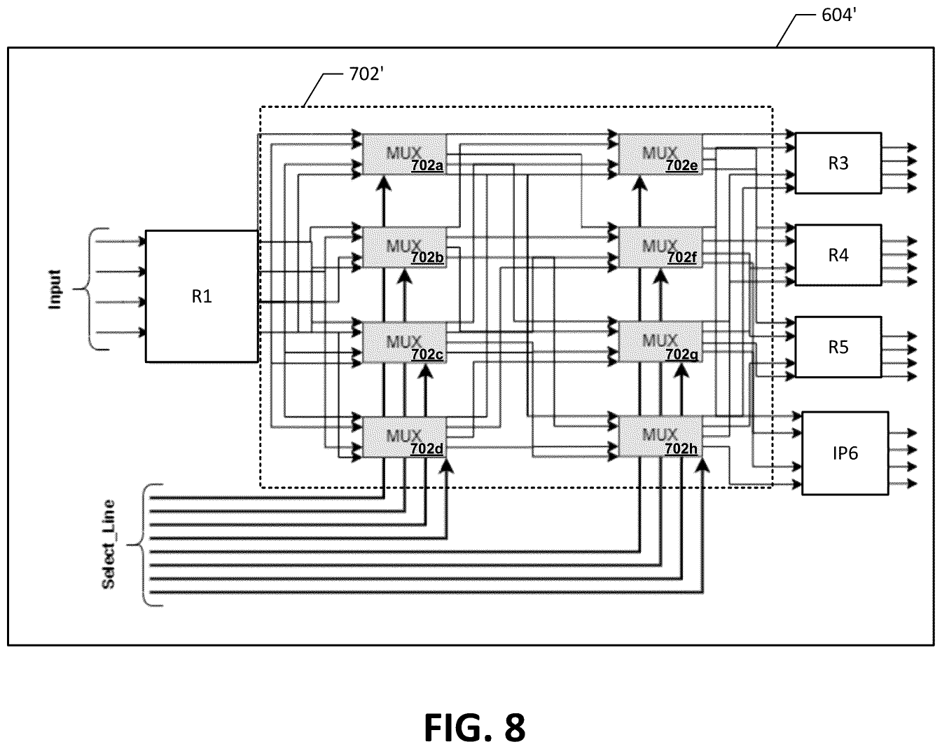

FIG. 8 illustrates a portion 604′ associated with the transformation of the SoC system 600 according to one or more embodiments of the present disclosure. The portion 604′ can be an alternate embodiment of the portion 604. For example, the portion 604′ can illustrate a transformation associated with multiple router and multiple ports of each router. As illustrated in FIG. 8, the portion 604′ can be transformed to include a multiplexer 702′ that is configured to conceal (e.g., transform) the connection from the router R1 to the IP core IP6. The multiplexer 702′ can be controlled via control bits (e.g., Select_Line) of a set of programmable registers (e.g., the set of programmable registers 704). In various embodiments, the multiplexer 702′ can be configured as a demultiplexer switch that includes a set of multiplexer switches 704a-h.

In various embodiments, the multiplexer 702′ can be implemented to redact an output port of the router R1. Accordingly, an input of the router R3, the router R4, the router R5 and the IP core IP6 can be connected to an output of the multiplexer 702′. To manage connections between the router R1, the router R3, the router R4, the router R5 and/or the IP core IP6, a multiplexer switch of the set of multiplexer switches 704a-h can be implemented for each input port of the router R3, the router R4, the router R5 and the IP core IP6. Additionally, the set of multiplexer switches 704a-h can be controlled via the control bits (e.g., Select_Line) provided by a set of programmable registers (e.g., the set of programmable registers 704). Accordingly, a transformed design with the router R1 obfuscated through redaction using the set of multiplexer switches 704a-h can be provided.

Below is an exemplary algorithm performed according to one or more embodiments of the present disclosure for inserting a multiplexer at a router in an SoC:

Algorithm 1: Algorithm for Custom MUX Insertion

Input: Router [symbol] with source and destination connections [symbol]
[S [symbol] ], [symbol] [ [symbol] [symbol] ]
Output: Activation package for [symbol] : [symbol] [ [symbol] ], Act_Pkg
Source (DEMUX) Configuration

| | |
|---|---|
| 1: | for single Router connection [symbol] : [symbol] [S [symbol] ] , [symbol] [ [symbol] [symbol] ]. [symbol] [symbol] ← S [symbol] |
| 2: | for all S [symbol] in [symbol] [S], do |
| 3: | Generate MUX [symbol] |
| 4: | MUX input :MUX [symbol] [in [symbol] ] ← [symbol] [Sᵢ]. |
| 5: | MUX output :MUX [symbol] [out] |
| 6: | MUX_out_list append MUX [symbol] [out] |
| 7: | Store : P [symbol] = (in [symbol] S [symbol] [symbol] [symbol] MUX [symbol] [out] ] |
| 8: | RandomizeConnections(MUX [symbol] , [in [symbol] ]) |
| 9: | Sel [symbol] ← getIndex(MUX [symbol] , in [symbol] S [symbol] ) |
| 10: | Act_Pkg[ [symbol] ] append Sel [symbol] |
| 11: | end for |
| 12: | for all [symbol] [symbol] in [symbol] [ [symbol] [symbol] ], do |
| 13: | Generate MUX [symbol] : |
| 14: | MUX [symbol] [in [symbol] ] append P [symbol] [MUX [symbol] [out]] |
| 15: | MUX [symbol] [out] ← [symbol] [ [symbol] [symbol] ] |
| 16: | end for |
| 17: | end for |
| 18: | return Act_Pkg, MUX_out_list |

Destination (MUX) Configuration
Input: Router [symbol] with source and destination connections [symbol]
[S [symbol] ], [symbol] [ [symbol] [symbol] ], MUX [symbol] [out], MUX_out_list.
Output: Activation package for [symbol] : [symbol] [ [symbol] [symbol] ]. Act_Pkg

| | |
|---|---|
| 1: | for all Router connections [symbol] [symbol] : [symbol] [symbol] [symbol] [ [symbol] [symbol] ]. |
| 2: | MUX input :MUX [symbol] [in [symbol] ] ← MUX [symbol] [out] |
| 3: | MUX [symbol] [in [symbol] − 1] ← randomSelect(MUX_out_list, |
| | size-1) |
| 4: | MUX output :MUX [symbol] [out] |
| 5: | RandomizeConnections(MUX [symbol] [in [symbol] ]) |
| 6: | Sel [symbol] ← getIndex(MUX [symbol] in [symbol] MUX [symbol] [out] , |
| | [symbol] [symbol] ) |
| 7: | Act_Pkg[ [symbol] [symbol] _S [symbol] ] append Sel [symbol] |
| 8: | end for |
| 9: | return Act_Pkg |

[symbol]

indicates data missing or illegible when filed

In various embodiments, for each multiplexer switch Sᵢ such that there is a link router R→SL and each demultiplexer Dᵢ such that there is a link Dᵢ→R, a programmable MUX can be provided for each end of the router links. The function RandomizeConnections can provide non-determinism in connecting the outputs of a multiplexer to, for example, non-deterministically map candidate blocks to the outputs of the demultiplexer switch for R₁. Additionally, for each multiplexer insertion, bit pattern to be loaded to the control register to recover an original topology can be stored. The bit pattern for the demultiplexer switches (e.g., respective multiplexer switches) at the output (e.g., respective input) ports of router R can be referred to as the output (e.g., respective input) activation package for R. The bit pattern obtained by concatenating the activation packages of all routers in the NoC can be referred to as the activation package (e.g., Act_Pkg) of the NoC. In various embodiments, multiplexers can be inserted on a port of router R such that the control configurations induce topologies involving blocks that are already connected to a port of R. In various embodiment, one or more other routers R can be connected with other IP cores to create additional topologies under different control configuration. This can provide additional protection against SAT attacks and/or brute force adversaries.

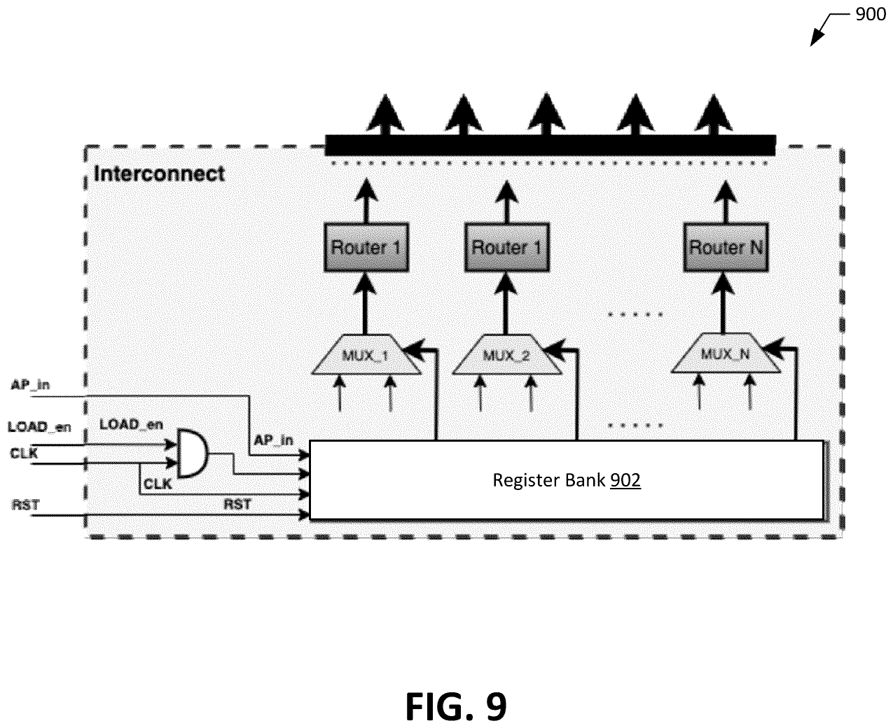

FIG. 9 illustrates an activation package loader circuit 900 according to one or more embodiments of the present disclosure. The activation package loader circuit 900 can be utilized to load an activation package (e.g., the activation package 312) onto an SoC. For example, the activation package loader circuit 900 can be utilized to configure programmable control bits for respective multiplexers of an obfuscated SoC. An NoC design transformed by an obfuscation may realize an original topology of the NoC when the registers connected to the controls of the multiplexers and/or multiplexer switches are configured with the activation package. In various embodiments, the activation package loader circuit 900 can be configured to load the activation package through a bit shifting technique. The activation package loader circuit 900 includes a register bank 902. The register bank 902 can be an activation package load register (e.g., AP_LOAD_REG) for holding the activation package of the NoC. The register bank 902 can utilize a Serial Input Parallel Output (SIPO) mechanism where the activation package is provided one bit at a time per each clock cycle through the 1-bit primary input AP_in. The signal LOAD_en can be gated with the clock and the bits can be loaded into the shift register only when LOAD_en is asserted. Once the entire activation package is loaded into the register, the LOAD_en can be de-asserted and the parallel outputs of the register can be connected to the select lines of the respective multiplexers MUX_1, MUX_2 and/or MUX_3. An output of the respective multiplexers MUX_1, MUX_2 and/or MUX_3 can be connected to respective routers (e.g., Router 1, Router 2 and/or Router 3) and/or respective IP cores.

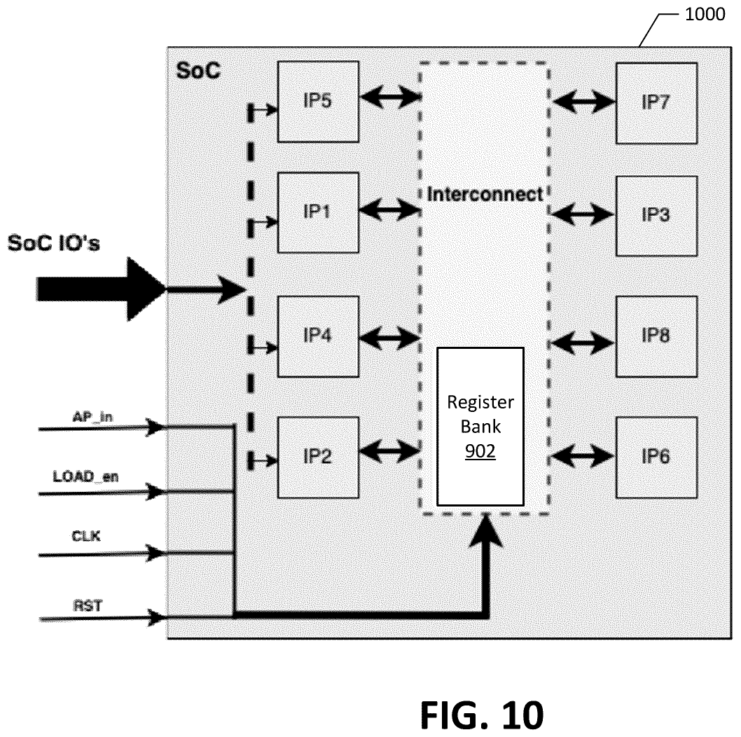

FIG. 10 illustrates a transformed SoC 1000 that includes the activation package loader circuit 900 according to one or more embodiments of the present disclosure. For example, an interconnect of the SoC 1000 can include the register bank 902 to facilitate configuration of respective multiplexers for respective connections to IP cores (e.g., IP1, IP2, IP3, IP4, IP5, IP6 and IP7) of the SoC 1000.

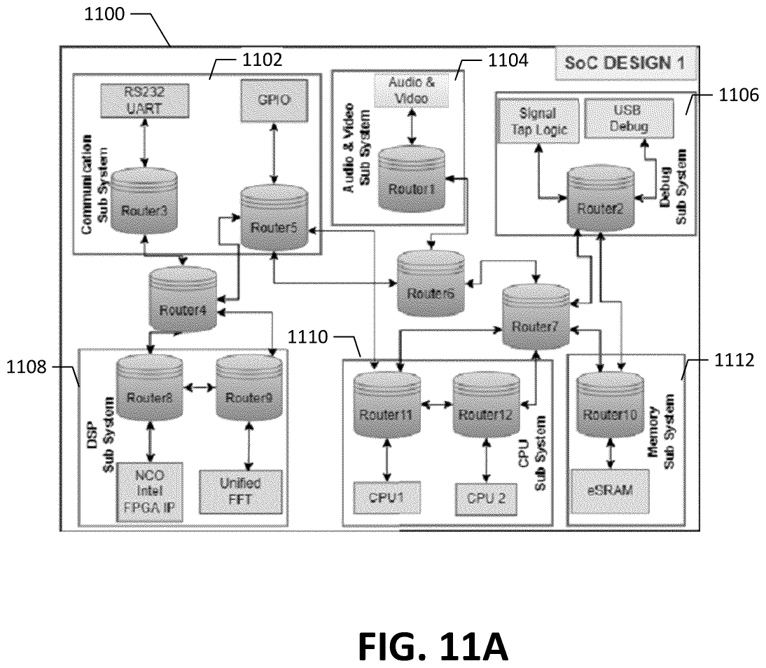

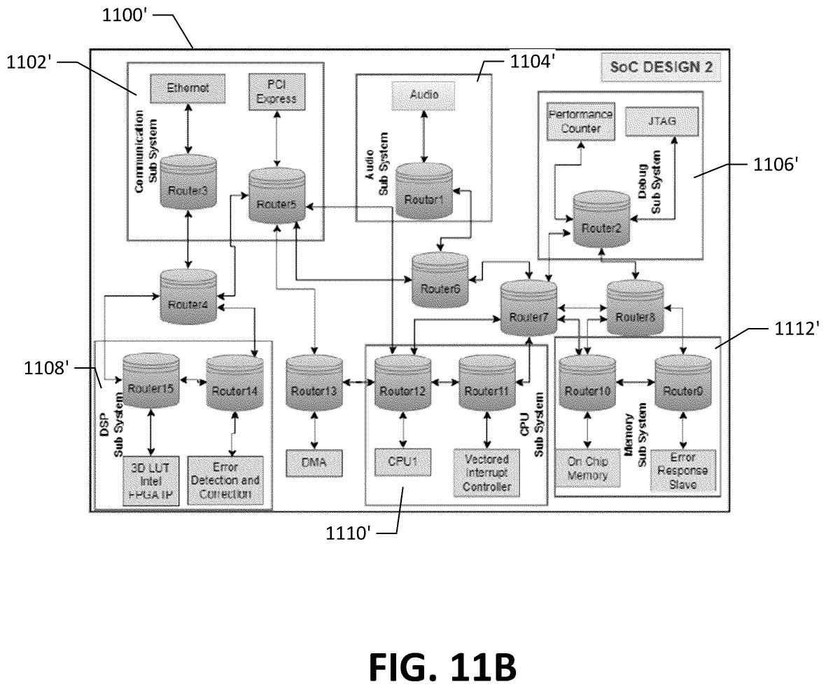

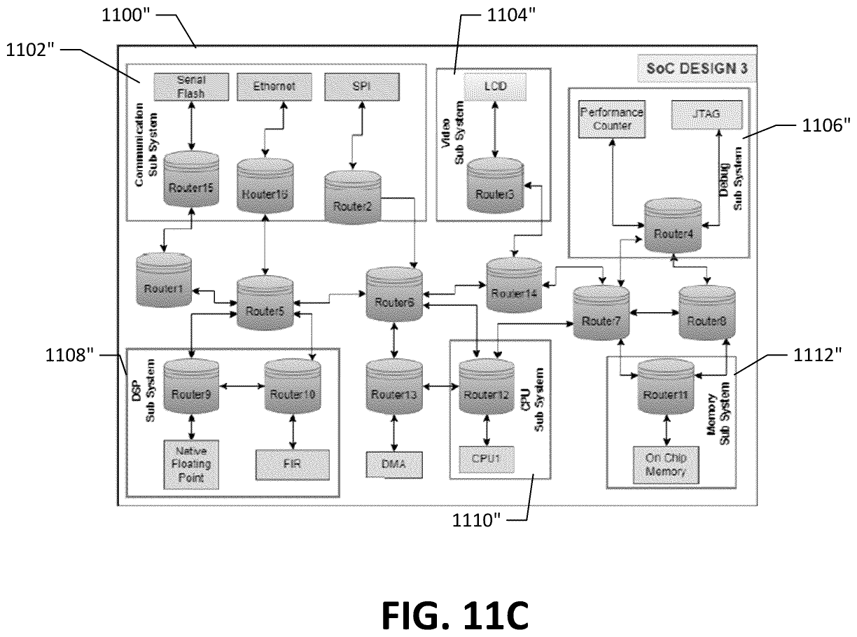

FIG. 11A illustrates an example SoC 1100 according to one or more embodiments of the present disclosure. The SoC 1100 includes a set of routers (e.g., Router 1, Router 2, Router 3, Router 4, Router 5, Router 6, Router 7, Router 8, Router 9 and Router 10) that connect a communication subsystem 1102, an audio and video subsystem 1104, a debugging subsystem 1106, a digital signal processing (DSP) subsystem 1108, a central processing unit (CPU) subsystem 1110 and a memory subsystem 1112.

FIG. 11B illustrates an example SoC 1100′ according to one or more embodiments of the present disclosure. The SoC 1100 includes a set of routers (e.g., Router 1, Router 2, Router 3, Router 4, Router 5, Router 6, Router 7, Router 8, Router 9 and Router 10) that connect a communication sub system 1102′, an audio and video sub system 1104′, a debugging sub system 1106, a DSP subsystem 1108′, a CPU subsystem 1110′ and a memory subsystem 1112′.

FIG. 11C illustrates an example SoC 1100″ according to one or more embodiments of the present disclosure. The SoC 1100 includes a set of routers (e.g., Router 1, Router 2, Router 3, Router 4, Router 5, Router 6, Router 7, Router 8, Router 9 and Router 10) that connect a communication subsystem 1102″, an audio and video subsystem 1104″, a debugging subsystem 1106, a DSP subsystem 1108″, a CPU subsystem 1110″ and a memory subsystem 1112″.

In various embodiments, a CPU subsystem can include two NIOS processors; a memory subsystem can include an on-chip memory and a DMA controller; a communication subsystem can includes an SPI module, an Ethernet, and a Serial Flash module; and/or a debugging subsystem can include a JTAG and a Performance Counter IP. Additionally, the SoC 1100, the SoC 1100′ and the SoC 1100″ can respectively include different router connections between subsystems. Each of the SoC 1100, the SoC 1100′ and the SoC 1100″ can provide improved security and/or power consumption by utilizing adaptive logic modules, intelligent multiplexers, and/or a set of logic controllers to provide obfuscation.

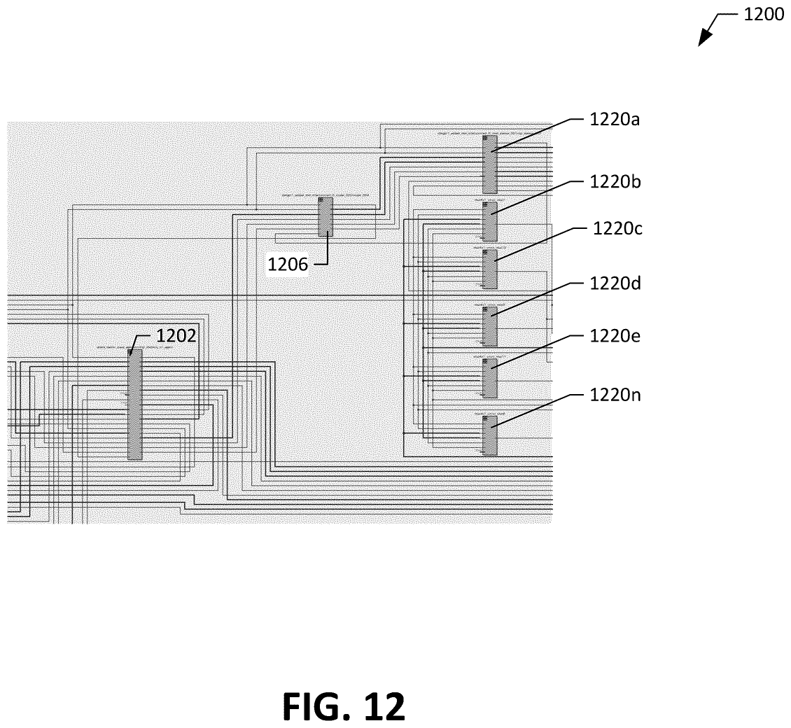

FIG. 12 illustrates a system 1200 associated with topology obfuscation according to one or more embodiments of the present disclosure. The system 1200 can provide a configurable multiplexer-demultiplexer implementation for one or more embodiments of the topology obfuscation 110. In various embodiments, the system 1200 can provide an optimized implantation of the topology obfuscation 110. The system 1200 includes an IP core 1212, a router 1206, and one or more multiplexers 1220a-n. In various embodiments, the IP core 1212 can be an IP core from the one or more IP cores 112a-n. The IP core 1212 and the router 1206 can correspond to at least a portion of an SoC architecture such as, for example, the SoC architecture 202. In various embodiments, the topology obfuscation 110 can replace one or more static fabric connections for the SoC architecture with the one or more multiplexers 1220a-n. The one or more multiplexers 1220a-n can be configured as a set of programmable multiplexers to provide optimized topology obfuscation. In various embodiments, the one or more multiplexers 1220a-n can be configured for control based on one or more programmable bits (e.g., the one or more programmable control bits 118) in order to provide optimized topology obfuscation. In various embodiments, the one or more multiplexers 1220a-n can be configured as a set of multiplexers to reduce multiplexer-demuliplexer heterogeneity associated with topology obfuscation.

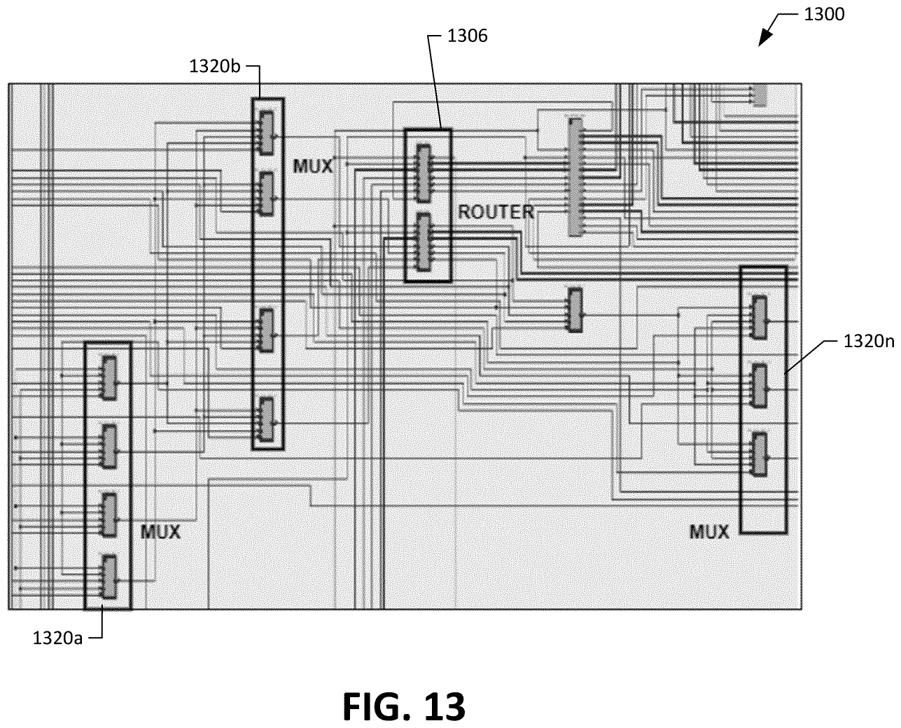

FIG. 13 illustrates a system 1300 associated with topology obfuscation according to one or more embodiments of the present disclosure. The system 1300 can provide routing topology obfuscation for one or more embodiments of the topology obfuscation 110. In various embodiments, the system 1300 can provide an optimized implantation of the topology obfuscation 110. The system 1300 includes one or more multiplexers 1320a-n and a router 1306 where the one or more multiplexers 1320a-n provide obfuscation of one or more connections associated with the router 1306. The one or more multiplexers 1320a-n can be configured as a set of programmable multiplexers to provide optimized topology obfuscation. In various embodiments, the one or more multiplexers 1320a-n can be configured for control based on one or more programmable bits (e.g., the one or more programmable control bits 118) in order to provide optimized topology obfuscation.

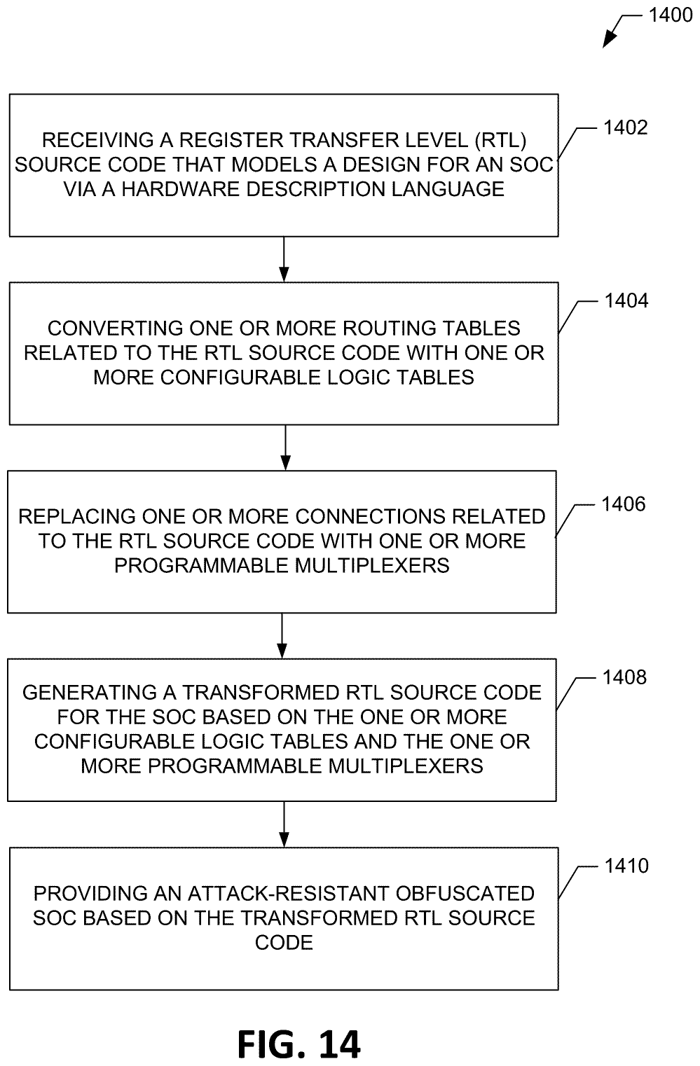

FIG. 14 illustrates a flowchart of a method 1400 for redacting NoC functionality in a SoC architecture according to one or more embodiments of the present disclosure. According to the illustrated embodiment, the method 1400 includes a step 1402 for receiving a Register Transfer Level (RTL) source code that models a design for an SoC via a hardware description language. Additionally, the method 1400 includes a step 1404 for converting one or more routing tables related to the RTL source code with one or more configurable logic tables. The method 1400 additionally includes a step 1406 for replacing one or more connections related to the RTL source code with one or more programmable multiplexers. The method 1400 additionally includes a step 1408 for generating a transformed RTL source code for the SoC based on the one or more configurable logic tables and the one or more programmable multiplexers. The method 1400 additionally includes a step 1410 for providing an attack-resistant obfuscated SoC based on the transformed RTL source code.

In certain embodiments, the converting the one or more routing tables includes determining a set of configurable parameters for the one or more configurable logic tables.

In certain embodiments, the replacing the one or more connections includes transforming a connection between a router and a hardware core of the SoC.

In certain embodiments, the replacing the one or more connections includes transforming a connection between a first router and a second router of the SoC.

In certain embodiments, the method 1400 additionally or alternatively includes generating a set of programmable control bits for the one or more programmable multiplexers based on the set of configurable parameters.

In certain embodiments, the method 1400 additionally or alternatively includes applying an activation package associated with the set of configurable parameters to the attack-resistant obfuscated SoC to obtain an original design for the SoC.

In certain embodiments, the one or more programmable multiplexers are related to one or more switch configurations for the SoC.

In certain embodiments, the method 1400 additionally or alternatively includes configuring the one or more programmable multiplexers as a set of multiplexers to reduce multiplexer-demuliplexer heterogeneity associated with topology obfuscation.

In certain embodiments, one or more steps (1402, 1404, 1406, 1408 and/or 1410) of the method 400 can be implemented in combination with one or more steps (1402, 1404, 1406, 1408 and/or 1410) of the method 1400.

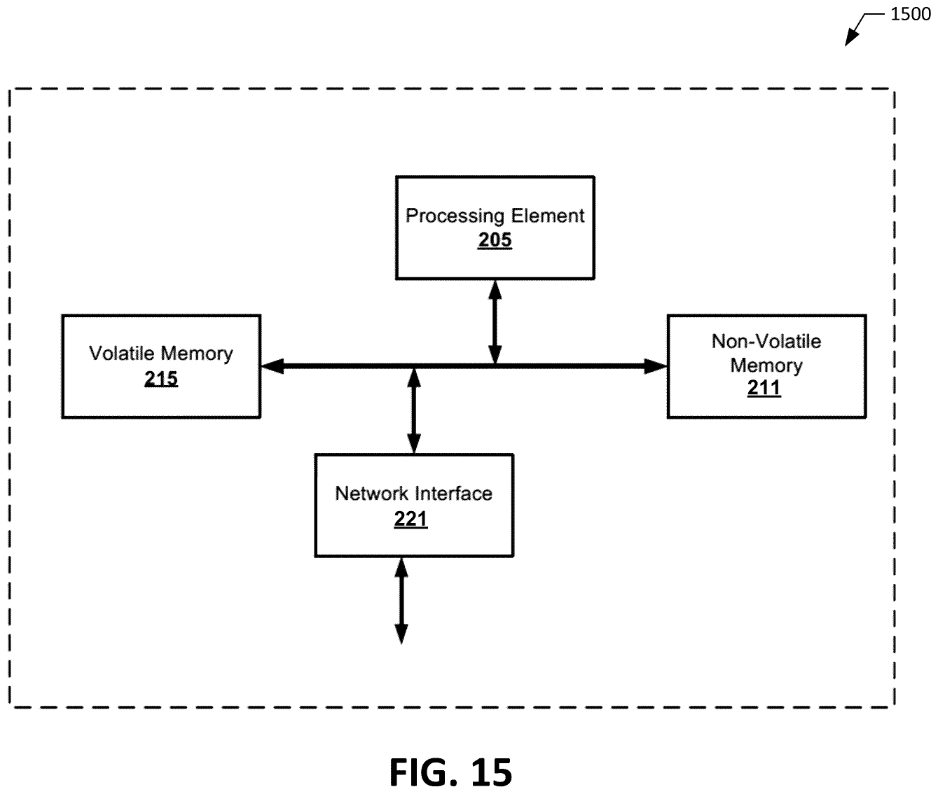

In an example embodiment, an apparatus for performing the method 1400 of FIG. 14 above may include a processor configured to perform some or each of the operations (1402, 1404, 1406, 1408 and/or 1410) described above. The processor may, for example, be configured to perform the operations (1402, 1404, 1406, 1408 and/or 1410) by performing hardware implemented logical functions, executing stored instructions, or executing algorithms for performing each of the operations. Alternatively, the apparatus may comprise means for performing each of the operations described above. In this regard, according to an example embodiment, examples of means for performing operations 1402, 1404, 1406, 1408 and/or 1410 may comprise, for example, the processor and/or a device or circuit for executing instructions or executing an algorithm for processing information as described above. In various embodiments, an apparatus for performing the method 1400 may correspond to apparatus 1500 illustrated in FIG. 15.

### B. Exemplary Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

FIG. 15 provides a schematic of an exemplary apparatus 1500 that may be used in accordance with various embodiments of the present disclosure. In particular, the apparatus 1500 may be configured to perform various example operations described herein to redact NoC functionality in an SoC architecture. In some example embodiments, the apparatus 1500 may be embodied by the obfuscation architecture 102.

In general, the terms computing entity, entity, device, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

Although illustrated as a single computing entity, those of ordinary skill in the field should appreciate that the apparatus 1500 shown in FIG. 15 may be embodied as a plurality of computing entities, tools, and/or the like operating collectively to perform one or more processes, methods, and/or steps. As just one non-limiting example, the apparatus 1500 may comprise a plurality of individual data tools, each of which may perform specified tasks and/or processes.

Depending on the embodiment, the apparatus 1500 may include one or more network and/or communications interfaces 221 for communicating with various computing entities, such as by communicating data, content, information, and/or similar terms used herein interchangeably that can be transmitted, received, operated on, processed, displayed, stored, and/or the like. Thus, in certain embodiments, the apparatus 1500 may be configured to receive data from one or more data sources and/or devices, as well as receive data indicative of input, for example, from a device.

The networks used for communicating may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks may have any suitable communication range associated therewith and may include, for example, global networks (e.g., the Internet), MANs, WANs, LANs, or PANs. In addition, the networks may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

Accordingly, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the apparatus 700 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), 5G New Radio (5G NR), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The apparatus 700 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In addition, in various embodiments, the apparatus 1500 includes or is in communication with one or more processing elements 205 (also referred to as processors, processing circuitry, and/or similar terms used herein interchangeably) that communicate with other elements within the apparatus 1500 via a bus, for example, or network connection. As will be understood, the processing element 205 may be embodied in several different ways. For example, the processing element 205 may be embodied as one or more complex programmable logic devices (CPLDs), microprocessors, multi-core processors, coprocessing entities, application-specific instruction-set processors (ASIPs), and/or controllers. Further, the processing element 205 may be embodied as one or more other processing devices or circuitry. The term circuitry may refer to an entirely hardware embodiment or a combination of hardware and computer program products. Thus, the processing element 205 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 205 may be configured for a particular use or configured to execute instructions stored in volatile or non-volatile media or otherwise accessible to the processing element 205. As such, whether configured by hardware, computer program products, or a combination thereof, the processing element 205 may be capable of performing steps or operations according to embodiments of the present disclosure when configured accordingly.

In various embodiments, the apparatus 1500 may include or be in communication with non-volatile media (also referred to as non-volatile storage, memory, memory storage, memory circuitry and/or similar terms used herein interchangeably). For instance, the non-volatile storage or memory may include one or more non-volatile storage or non-volatile memory media 211 such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or non-volatile memory media 211 may store files, databases, database instances, database management system entities, images, data, applications, programs, program modules, scripts, source code, object code, byte code, compiled code, interpreted code, machine code, executable instructions, and/or the like. The term database, database instance, database management system entity, and/or similar terms used herein interchangeably and in a general sense to refer to a structured or unstructured collection of information/data that is stored in a computer-readable storage medium.

In particular embodiments, the non-volatile memory media 211 may also be embodied as a data storage device or devices, as a separate database server or servers, or as a combination of data storage devices and separate database servers. Further, in some embodiments, the non-volatile memory media 211 may be embodied as a distributed repository such that some of the stored information/data is stored centrally in a location within the system and other information/data is stored in one or more remote locations. Alternatively, in some embodiments, the distributed repository may be distributed over a plurality of remote storage locations only. As already discussed, various embodiments contemplated herein use data storage in which some or all the information/data required for various embodiments of the disclosure may be stored.

In various embodiments, the apparatus 1500 may further include or be in communication with volatile media (also referred to as volatile storage, memory, memory storage, memory circuitry and/or similar terms used herein interchangeably). For instance, the volatile storage or memory may also include one or more volatile storage or volatile memory media 215 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like.

As will be recognized, the volatile storage or volatile memory media 215 may be used to store at least portions of the databases, database instances, database management system entities, data, images, applications, programs, program modules, scripts, source code, object code, byte code, compiled code, interpreted code, machine code, executable instructions, and/or the like being executed by, for example, the processing element 205. Thus, the databases, database instances, database management system entities, data, images, applications, programs, program modules, scripts, source code, object code, byte code, compiled code, interpreted code, machine code, executable instructions, and/or the like may be used to control certain aspects of the operation of the apparatus 1500 with the assistance of the processing element 205 and operating system.

As will be appreciated, one or more of the computing entity's components may be located remotely from other computing entity components, such as in a distributed system. Furthermore, one or more of the components may be aggregated, and additional components performing functions described herein may be included in the apparatus 1500. Thus, the apparatus 1500 can be adapted to accommodate a variety of needs and circumstances.

### C. Conclusion

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A method for redacting Network-on-Chip (NoC) functionality in a System-on-Chip (SoC) architecture, comprising:
receiving a Register Transfer Level (RTL) source code that models a design for an SoC via a hardware description language;
converting one or more routing tables related to the RTL source code with one or more configurable logic tables;
replacing one or more connections related to the RTL source code with one or more programmable multiplexers;
generating a transformed RTL source code for the SoC based on the one or more configurable logic tables and the one or more programmable multiplexers; and
providing an attack-resistant obfuscated SoC based on the transformed RTL source code.

2. The method of claim 1, wherein the converting the one or more routing tables comprises determining a set of configurable parameters for the one or more configurable logic tables.

3. The method of claim 2, further comprising:
generating a set of programmable control bits for the one or more programmable multiplexers based on the set of configurable parameters.

4. The method of claim 2, further comprising:
applying an activation package associated with the set of configurable parameters to the attack-resistant obfuscated SoC to obtain an original design for the SoC.

5. The method of claim 1, wherein the one or more programmable multiplexers are related to one or more switch configurations for the SoC.

6. The method of claim 1, further comprising:
configuring the one or more programmable multiplexers as a set of multiplexers to reduce multiplexer-demuliplexer heterogeneity associated with topology obfuscation.

7. The method of claim 1, wherein the replacing the one or more connections comprises transforming a connection between a router and a hardware core of the SoC.

8. The method of claim 1, wherein the replacing the one or more connections comprises transforming a connection between a first router and a second router of the SoC.

9. An apparatus comprising at least one processor and at least one memory including program code, the at least one memory and the program code configured to, with the at least one processor, cause the apparatus to at least:
receive a Register Transfer Level (RTL) source code that models a design for an SoC via a hardware description language;
convert one or more routing tables related to the RTL source code with one or more configurable logic tables;
replace one or more connections related to the RTL source code with one or more programmable multiplexers;
generate a transformed RTL source code for the SoC based on the one or more configurable logic tables and the one or more programmable multiplexers; and
provide an attack-resistant obfuscated SoC based on the transformed RTL source code.

10. The apparatus of claim 9, wherein the at least one memory and the program code are configured to, with the at least one processor, further cause the apparatus to at least:
determine a set of configurable parameters for the one or more configurable logic tables.

11. The apparatus of claim 10, wherein the at least one memory and the program code are configured to, with the at least one processor, further cause the apparatus to at least:
generate a set of programmable control bits for the one or more programmable multiplexers based on the set of configurable parameters.

12. The apparatus of claim 10, wherein the at least one memory and the program code are configured to, with the at least one processor, further cause the apparatus to at least:
apply an activation package associated with the set of configurable parameters to the attack-resistant obfuscated SoC to obtain an original design for the SoC.

13. The apparatus of claim 9, wherein the one or more programmable multiplexers are related to one or more switch configurations for the SoC.

14. The apparatus of claim 9, wherein the at least one memory and the program code are configured to, with the at least one processor, further cause the apparatus to at least:
configure the one or more programmable multiplexers as a set of multiplexers to reduce multiplexer-demuliplexer heterogeneity associated with topology obfuscation.

15. The apparatus of claim 9, wherein the at least one memory and the program code are configured to, with the at least one processor, further cause the apparatus to at least:
transform a connection between a router and a hardware core of the SoC.

16. The apparatus of claim 9, wherein the at least one memory and the program code are configured to, with the at least one processor, further cause the apparatus to at least:
transform a connection between a first router and a second router of the SoC.

17. A non-transitory computer storage medium comprising instructions, the instructions being configured to cause one or more processors to at least perform operations configured to:
receive a Register Transfer Level (RTL) source code that models a design for an SoC via a hardware description language;
convert one or more routing tables related to the RTL source code with one or more configurable logic tables;
replace one or more connections related to the RTL source code with one or more programmable multiplexers;
generate a transformed RTL source code for the SoC based on the one or more configurable logic tables and the one or more programmable multiplexers; and
provide an attack-resistant obfuscated SoC based on the transformed RTL source code.

18. The non-transitory computer storage medium of claim 17, wherein the operations are further configured to:
determine a set of configurable parameters for the one or more configurable logic tables.

19. The non-transitory computer storage medium of claim 18, wherein the operations are further configured to:
generate a set of programmable control bits for the one or more programmable multiplexers based on the set of configurable parameters.

20. The non-transitory computer storage medium of claim 18, wherein the operations are further configured to:
apply an activation package associated with the set of configurable parameters to the attack-resistant obfuscated SoC to obtain an original design for the SoC.
